(19) United States
(12) Patent Application Publication
(10) Pub. No.: US 2025/0327185 A1
(43) Pub. Date: Oct. 23, 2025

(54) FAIL-SAFE CONTROL IN SUBSTRATE PROCESSING SYSTEMS

(71) Applicant: Applied Materials, Inc., Santa Clara, CA (US)

(72) Inventors: Daemian Raj Benjamin Raj, Fremont, CA (US); Collen Ziwei Leng, San Jose, CA (US); Hassan Ali, Santa Clara, CA (US); Venkatanarayana Shankaramurthy, San Jose, CA (US); Peter Miles Standish, San Jose, CA (US); Travis Clark Mazzy, San Jose, CA (US); Thorsten Kril, Santa Cruz, CA (US); Ashish A Shah, Sunnyvale, CA (US); Bharath Kumar Hanchanoor Rathnakara Gowda, Cupertino, CA (US); Hemanth Konanur Nagendra, Santa Clara, CA (US); Yu Jin, Los Altos, CA (US)

(21) Appl. No.: 19/173,521

(22) Filed: Apr. 8, 2025

Related U.S. Application Data
(60) Provisional application No. 63/636,671, filed on Apr. 19, 2024.

(51) Int. Cl. C23C 16/52; C23C 16/455

(52) U.S. Cl. CPC C23C 16/52; C23C 16/45561

(57) ABSTRACT

A method includes: performing auto-classification of fluids to be used in a substrate processing system; identifying portions of the substrate processing system; performing positional awareness of the fluids associated with one or more of the portions of the substrate processing system; and causing substrate processing via substrate processing equipment based on the auto-classification, the portions of the substrate processing system, and the positional awareness.

### RELATED APPLICATIONS

This application claims the benefit of U.S. Provisional Patent Application No. 63/636,671, filed Apr. 19, 2024, the contents of which are incorporated by reference in its entirety herein.

### TECHNICAL FIELD

The present disclosure relates to control in manufacturing systems, such as substrate processing, and in particular to fail-safe control in substrate processing systems.

### BACKGROUND

Products are produced by performing one or more manufacturing processes using manufacturing equipment. For example, substrate processing equipment is used to process substrates.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In an aspect of the disclosure, a method includes: performing auto-classification of fluids to be used in a substrate processing system; identifying portions of the substrate processing system; performing positional awareness of the fluids associated with one or more of the portions of the substrate processing system; and causing substrate processing via the substrate processing system based on the auto-classification, the portions of the substrate processing system, and the positional awareness.

In another aspect of the disclosure, a non-transitory machine-readable storage medium stores instructions which, when executed cause a processing device to: perform auto-classification of fluids to be used in a substrate processing system; identify portions of the substrate processing system; perform positional awareness of the fluids associated with one or more of the portions of the substrate processing system; and cause substrate processing via the substrate processing system based on the auto-classification, the portions of the substrate processing system, and the positional awareness.

In another aspect of the disclosure, a system includes: memory; and a processing device coupled to the memory, the processing device to: perform auto-classification of fluids to be used in a substrate processing system; identify portions of the substrate processing system; perform positional awareness of the fluids associated with one or more of the portions of the substrate processing system; and cause substrate processing via the substrate processing system based on the auto-classification, the portions of the substrate processing system, and the positional awareness.

### BRIEF DESCRIPTION OF THE DRAWINGS

The present disclosure is illustrated by way of example, and not by way of limitation in the figures of the accompanying drawings.

FIGS. 1-2 illustrate systems associated with fail-safe control, according to certain embodiments.

FIG. 3 is a flow diagram of a method associated with fail-safe control, according to certain embodiments.

FIGS. 4A-C are flow diagrams of methods associated with fail-safe control, according to certain embodiments.

FIG. 5 is a block diagram illustrating a computer system, according to certain embodiments.

### DETAILED DESCRIPTION

Described herein are technologies directed to fail-safe control in substrate processing systems (e.g., intelligent software architecture fail-safe control, intelligent tool and chamber software control architecture that has methods to track, monitor, and provide fail-safe mechanism to prevent undesirable fluid chemistry reaction such as particulate generation due to interactions between incompatible fluids).

Conventional software and operation architecture is not intelligent, is task orientated, and requires users to be experts in hundreds of tasks done in proper sequence to prevent, for example, incompatible fluid reaction for long term reliability. Conventionally, there are limited fail-safe mechanisms, notifications, tracking, and monitoring of key sensor and operations in sequence. This may cause unintended chemical reaction resulting in dusting. Conventionally, there is no intelligence on positional awareness of fluid delivery components or even which fluid or fluids might be charging any particular segment (e.g., component, piping, location where fluid may pass through and/or be present, etc.) of the fluid delivery system, process chamber, or exhaust systems. This causes waste of material and time, reduced yield, increased errors, substrates not meeting threshold values (e.g., bad substrates), damage to equipment, a waste of energy. This may also cause an increase in errors resulting in more corrective actions (e.g., maintenance, cleaning, replacement of components, etc.) being required.

The devices, systems, and methods disclosed herein provide solutions to these and other shortcomings of conventional systems.

A processing device may perform auto-classification of fluids that are to be used in a substrate processing system. In some embodiments, the auto-classification of the fluids is associated with classification of one or more of an inert fluid, a reactive oxidizing fluid, a non-reactive oxidizing fluid, or a corrosive fluid.

The processing device may identify portions of the substrate processing system. In some embodiments, the portions of the substrate processing system include piping. At least one of the fluids may pass through at least one of the one or more portions (e.g., piping) of the substrate processing system.

The processing device may perform positional awareness of the fluids associated with one or more of the portions of the substrate processing system. The positional awareness may identify which fluid is in which piping at which time and which fluid is to subsequently flow through that same piping.

The processing device may cause substrate processing via the substrate processing system based on the auto-classification, the portions of the substrate processing system, and the positional awareness. In some embodiments, to cause the substrate processing, the processing device is to cause a flushing of a first portion (e.g., first piping) of the substrate processing system and, responsive to the flushing, cause a first fluid to pass through the first portion (e.g. the first piping) of the substrate processing system.

The present disclosure may (e.g., via intelligent autonomous software) prevent fluid reaction residue or other malfunctions caused by incorrect sequence of fluid flow and evacuation of incompatible fluids within a system. The present disclosure may provide intelligent elements that classify fluids (e.g., process chemicals such as gases or liquids) and the rules for managing them (e.g., pump, purge, etc.) and the interactions between them. The present disclosure may provide an automated wizard and service to complete tasks (e.g., complex maintenance large, sequenced tasks).

The present disclosure may (e.g., via system-sentry intelligent autonomous software controls) create one or more of the following (e.g., base or architectural items):
1) classification and tracking of fluids in system and wetted locations;
2) positional awareness of valves relative to process chamber, gas panel or other segments of the processing system; and/or
3) segmenting of the substrate processing system (e.g., defining portions of the substrate processing system such as one or more of fluid panel, input fluid lines, chamber, exhaust, etc.) and incorporating a timer for each segment to monitor the presence of each fluid and to initiate fluid species and time-dependent actions in each segment of the system, status, and visual—this may be used to define various behavior rules and sequences in each segment including but not limited to:
a) co-flow;
b) sequential flow;
c) inert flush; and/or
d) pump and purge.

The processing device (e.g., by using this control scheme) may prevent unwanted fluid phase reactions within portions of the system in a more efficient and reproducible manner than conventional systems.

Aspects of the present disclosure result in technological advantages. The present disclosure may create an intelligent and autonomous software-tool ecosystem of operation that reduces (e.g., significantly reduces) user manual task operation and sequence requirements decisions compared to conventional systems. The present disclosure may allow fewer manual, service routines (e.g., conducted by the user) to operate or service the tool compared to conventional systems. The present disclosure may provide different elements (e.g., classification and tracking of all process chemicals (e.g., fluids, such as gases and liquids), visual representation of wetted location across pre-defined system segments that require segment-specific behaviors, etc.) that do not exist in conventional systems. The present disclosure may provide chemical classification, timers, and positional awareness that are combined to be used by a processing device (e.g., to be used as a system) to prevent mis-operation that conventionally causes unwanted reactions between incompatible fluids, liquids, gases, and/or chemicals.

Conventionally, there are many opportunities for operator error and various unintended chemical interactions that cause tool malfunction and/or failure. The present disclosure may provide architectural changes and elements that work in cohesion to autonomously decide actions, track, monitor, and/or resolve violation of rules of operation or processing faults that may cause issues such as substrate processing system contamination due to formation of solid byproducts of unwanted reactions between incompatible fluids.

In some embodiments, the present disclosure provides autonomous software controls, fluid classification, and/or automated tasks to manage interactions between process chemicals or between process chemicals and unwanted system impurities (e.g., residual oxygen or moisture present in the tool after certain maintenance operations).

The present disclosure may provide improvement of tool software controls architecture to prevent unwanted reactions between incompatible fluids.

One common consequence of such unwanted reactions between incompatible fluids within the wafer processing tool is the formation of solid residues. These residues can lead to defects on the device wafer processed in the tool or to other types of decreased tool performance such as process drift or the need for unscheduled tool maintenance.

One example of unwanted fluid reactions involves precursor-related dusting of fluid lines. The frequency of occurrence may be increasing even on mature high-volume manufacturing (HVM) products and new products with similar applications due to increasingly stringent processing requirements as tool users strive to increase system throughput or to meet performance requirements for advanced technology nodes. Occurrences on same chambers in the HVM fleet may repeat, even after best known methods (BKMs) for setup, configuration, recipe, and procedures implemented by subject-matter experts.

This may cause erosion of confidence and trust with users. This may also cause cost implications for parts replacement due to contamination, extended tool down time, and waste of material (e.g., user wafer scrap).

The development of technology (e.g., artificial intelligence (AI), the AI era) causes greater needs on computing and may result in unprecedented industry growth. Substrate processing (e.g., semiconductor processing) needed to support this next wave of growth in the computing industry is expanding at a great pace. Training local subject-matter experts or transporting subject-matter experts to substrate processing facilities may be used for substrate processing architecture of tool operation (e.g., heavily dependent on manual user operation) may not be sustainable for such rapid growth. Conventional solutions are not able to scale training of subject-matter experts needed for operation of substrate processing tools. Changes in way substrate processing tools operate may be needed to support this rapid growth. In addition, the present disclosure may enhance tool operation by providing software intelligence and autonomous controls that limit user interventions that conventionally are prone to human operator error.

Chamber and process fluid delivery architecture may conventionally have high vulnerability to “dusting” (i.e., formation of solid reaction residues) anytime there is a possibility of reactions between incompatible chemicals such as with moisture or O₂ sensitive chemicals such as silane, TEOS (tetraethyl orthosilicate) or TEPO (triethylphosphate) precursors.

Conventionally, software and controls architecture may lack monitoring and tracking of events or process sequences that may cause dusting (e.g., precursor fills chamber volume and then oxidizer fills same volume). This may especially be true when the tool has been put in a maintenance, or offline, mode during tool start-up or maintenance operations. Conventional systems have no fail-safe mechanism. Conventionally there are no intervention mechanisms (e.g., prevention) so that user actions can inadvertently lead to dusting. In addition, conventionally, there are no warnings (e.g., notifications) to inform users of actions that could lead to dusting or that some event has caused dusting.

Conventionally, there are multiple flow paths for each process chemical within the tool, forming an often complex flow network. Partly due to this complexity, there typically is no awareness (e.g., positional awareness) of where each process chemical is within the complex flow network used to transport process chemicals to the process chamber or out of the process chamber through the chamber or tool exhaust system. In addition, due to this potential flow network complexity, typical processing chamber or tool control systems do not track or properly account for the interrelationships of the various path flows or intersection points within the process chemical transport flow network (i.e., typical control systems lack positional awareness of various elements of the system to be controlled). Consequently, many of the control decisions in a typical processing tool control system are made without the proper context of where various process chemicals are located within the process tool (i.e., positional awareness).

Conventionally, tool operations recovery is not autonomous or intelligent. These operations are typically done manually with the tool or chamber offline and are highly dependent on user experience and skill even when procedures are well documented. Typical tasks include (but are not limited to) preventive maintenance, chamber matching, and hardware replacement or calibration.

Conventionally, preventive maintenance, recipe, and/or service recovery may rely heavily on manual control using experience-based rules-of thumb with little or no guidance to users. Conventionally, depending on the skill of the user, these manual operations can consist of ad hoc series of tasks and sequences that are originally independently defined and later combined by the user to address a given situation. Due to the ad hoc nature of these process sequences, there is typically a high risk of chamber or tool faults during even nominally well-documented procedures and a high degree of user-to-user variability in observed outcomes.

One example of operator error in a conventionally manual procedure is insufficient evacuation and dry down in substrate processing systems. Conventionally, there are no mandatory checks to do fluid (e.g., gas-phase precursor) evacuation and/or drying in the chamber and chemical delivery and exhaust lines before venting to atmosphere. Conventionally, chamber service vent and/or cycle-purge routines do not involve the entire fluid (e.g., precursor) path. Conventionally, the same delay post chamber open is used to dry down chamber and process chemical delivery and exhaust lines before fluid (e.g., precursor) flow and/or reintroduction. Conventionally, there is also limited protection if a service or recovery routine faults out in the middle and no intelligence to restart the routine at a proper step, or operation, in the sequence to prevent dusting. Conventionally, a user is to intervene or the system will wait indefinitely.

Resuming tool operation without taking the proper precautions to prevent unintended mixing of incompatible substances within the system (both process chemicals and residual environmental contaminants such as moisture) can result in undesired reactions generating contamination from solid residues or, in extreme situations, unsafe operating conditions that can damage equipment or harm personnel.

Conventionally fluid valve functionality may have no automated routine to check or verify all valve operations (e.g., open, close) which may be due to many failures such as software setup errors and other bugs and hardware errors such as set-up errors and other hardware failures that result in, among other issues, leaky valves, or valve leak-by.

Conventionally, procedure-driven tool operation may include navigating chamber manuals for the appropriate procedure or set of procedures. There are many opportunities for human operator error in this modality of tool operation. There may be many different pre-conditions listed over many pages and scattered across the manual. Users may become lost easily. Conventional instructions may not include time dependencies of each operation (e.g., running a leak check and subsequently keeping the tool idle for extended periods of time without pumping may cause moisture to enter the system and to remain present when process chemicals are eventually reintroduced into the tool).

Conventionally, procedure-driven tool operation may include checking the process chamber and the fluid delivery and exhaust lines for leaks. Conventionally, this operation may be performed manually. Depending on operator skill level, this operation often involves referencing written procedures or manuals of varying complexity and quality. Due to the complexity of the systems involved, written manuals will often be thick volumes with multiple cross-referenced sections with, for example, process gas- specific and system segment maximum allowable leak rates and testing preconditions and routines for handling and then testing various system interlocks that may need to be managed during and after the leak check. Documentation for these complex manual operations may be a tedious maze for users to navigate and, depending on operator skill or even fatigue, can often lead to operator errors.

Conventionally, there may be a gap in approaches. Multiple stitched preprogrammed routines (or recipes), services, and commands may be used. If or when an error occurs or something faults, the system may be offline and may require manual troubleshooting. The state of the various portions of the tool such as process chamber, fluid lines, and gas panel may be unknown when faulting and the next safe operation(s) may be unknown after recovery from the fault condition. It may be unknown whether the operations are to be restarted from the first operation, whether a few hours may be added, and/or whether it is safe to restart from the first operation or if a given action will result in dusting or any other fault condition.

Positional awareness may involve knowledge of the interrelationships between specific flow path volumes and flow control hardware such as valves in addition to the location of flow network intersection points and where within the flow network or process chamber each process chemical is located. There may be multiple segments of chamber breakdown, such as one or more of fluid sticks, fluid delivery lines, chamber lid manifold, piping to chamber, and/or internal volume of processing chamber.

Conventional software commands and controls architecture does not typically keep track of or define actions with positional awareness taken into full consideration.

There may be many flow paths for fluids (e.g., precursors, oxidizers, and other process chemicals). This impacts where fluids wet surfaces or can be trapped. Examples of flow paths for process chemicals in a typical substrate processing tool can include one or more of fluid flow to the processing chamber, fluid flow to the chamber lid, fluid flow through the mass flow controller (MFC), and/or fluid flow via a purge chamber.

Conventional software does not have positional awareness or track wetted path. Conventional software does not have intelligence of what is chamber, divert, foreline, lid, and/or fluid delivery line. Conventional software does not have intelligence in code that can segment by portion (e.g., area or location) of the substrate processing system. In conventional software, all paths and future permutations are defined by manual input (e.g., no intelligence to reference past path or tag logic).

Conventional residual fluid evacuation may be performed. Going offline may provide complete autonomy. Manual control may provide full access to user to do many things with fluid flows. In a conventional example, lid valves may be NO (normally open) and a user can flow fluid (e.g., precursor, oxidizer) and fill a whole chamber volume and connected fluid lines all the way to clean final in gas panel. Shortly thereafter, a user can command flow of an oxidizer, such as oxygen, through the system. If, for example, there is insufficient time to pump out incompatible gases such as silane from all volumes and since there typically is no mandatory restriction in any form to the user preventing introduction of incompatible gases into a given portion of the system, there can be a high risk of unwanted reactions resulting in solid residue formation in multiple areas of the tool.

Another example includes the use of mass flow controllers (MFC) to verify flow. A user can pick any fluid combination to run sequentially. In a conventional example, a user may pick fluids (e.g., precursor, oxidizer, purging fluid, etc.) and then these will be run sequentially. MFC may close chamber iso-valve to pressurize to fill all open channels. It may be pumped down to a threshold pressure and then the next fluid may be started which causes dusting. Cycle purge or evacuation of all open channels may not be required or warned to user.

The present disclosure may solve these and/or other issues.

The present disclosure (e.g., via processing logic of a processing device, of a server device, of a client device, etc.) may perform auto-classification of fluids. A classification may be provided for all fluids and/or fluid mixtures (e.g., in a substrate processing repository) for a mass flow controller (MFC) device.

The fluids and fluid mixtures may be classified (e.g., fluid classification). Definitions and functionalities (e.g., all definitions and functionalities) of fluid delivery and exhaust line behavior may be classified, such as compatibility, co-flow, sequential flow, required inert flush, pump out and cycle purge, sequence pre and post flowing pyrophoric or corrosive fluids, etc. These may be hard-coded in software and system dashboard.

The present disclosure may provide positional awareness and/or segmentation (e.g., of the fluids). The present disclosure may tie fluid classification compatibility to allow co-flow or disallow by segment. For example, a first fluid (e.g., precursor, oxidizer, etc.) may not co-flow or co-exist in one or more segments for a second fluid (e.g., a purging fluid, O₂) or one or more segments for a third fluid (e.g., toxic fluid, corrosive fluid, etc.). The software may not even allow to configure as such. The present disclosure may, for example, tie fluid classification to cause (e.g., mandate) flow of specific process chemical types (e.g., gas type such as inert) post specific process chemical flow in shared or non-shared segments before allowing subsequent flows of incompatible process chemicals. For example, after a first fluid (e.g., precursor, oxidizer) flows through one or more segments, flow of any inert fluid through the next segment may be caused (e.g., mandated) by detour or recipe operation. An algorithmic-logic library may continue to be built as there are new fluids and learnings (e.g., machine learning).

The present disclosure may provide timers, status, and segment defined reset actions or operation sequences. The present disclosure may provide control offline (e.g., dusting safe state when offline reached). The present disclosure may provide multiple online states ascending allowed actions (e.g., automated). The present disclosure may control (e.g., provide wizards for) gas panel services (e.g., software-user interaction for auto and/or manual operations). The present disclosure may provide interlocks and other sensors to determine the state and the next operations.

The present disclosure may provide a graphical user interface (GUI) to display portions of a substrate processing system (e.g., segments wetted with particular fluids, when particular fluid passed through particular segments, operations in particular segments). In some embodiments, a portion of a substrate processing system may have no restrictions of types of fluid. In some embodiments, a portion of a substrate processing system may have restrictions of moisture. In some embodiments, a portion of a substrate processing system may have a state of charged, residual, dry, or moisture. In some embodiments, the present disclosure provides chambers and/or loadlocks and sensors for action, prevention, and/or diagnostics. The sensors may provide sensor data indicative of one or more of moisture ingress, normal vent, abnormal vent, chamber gradual leak (e.g., after long time), chamber gross leak, pump fail, etc.

Each fluid may have a class label, co-flow restrictions (e.g., segment restrictions), sequential flow restrictions (e.g., pump/purge minimum requirements to flow a potentially restricted next fluid, through which segment, pump through upstream), cycle purge (e.g., minimum requirements), and/or venting (e.g., minimum requirements, pump through final, pump through upstream, stick leak-rate, etc.). The class labels may include inert (I), oxidizer (O), toxic oxidizer (TO), non-reactive oxidizer (NRO), toxic (T), liquid (L), pyrophoric (P), moisture sensitive (MS), and/or corrosive (C), or any other classification category as may be deemed useful for specific tool applications.

In some embodiments, the present disclosure may provide (e.g., via basic autopilot) tracking and awareness of one or more fluids (e.g., key fluids, precursor, oxidizer, etc.) via manual configuration. In some embodiments, there may not be intelligence by fluid identifier (e.g., user inputs selected fluids in configuration for monitoring and controls). There may be a timer for all volumes by segments. There may be an indication of fluid line states (e.g., residual, charged, dry, moisture) and flags for a timer. There may be a more conservative approach on evacuation (e.g., all fluids selected may be evacuated from segments, rolling cycle purge of all sticks selected). There may not be an automatic pop-up, there may be one click to launch recovery (e.g., receive notification, to go to separate service dashboard, such as a rolling cycle purge). There may be prevention of fluid (e.g., precursor, oxidizer) flow after a chemical and segment dependent critical elapsed time in volumes that have moisture ingression. Example volumes controlled can include processing chambers, wafer transfer chambers, and load lock chambers.

In some embodiments, the present disclosure may provide positional awareness of valves. The present disclosure may provide segments tracking and awareness of all fluids. The present disclosure may provide classification of fluids defined exclusions between classes fully enforced (e.g., co-flow, sequential flow restrictions, and/or exceptions). The present disclosure may provide shared segments sharing incompatible fluids sequential flow restrictions. Some examples may use purge, pump, or inert flow by time, to then allow incompatible fluids. The present disclosure may enable more efficient maintenance and troubleshooting actions to minimize system downtime. The present disclosure may provide a wizard for key services (e.g., MFC change, etc.). The present disclosure may provide a visual graphical dashboard for wetted fluids and states.

In some embodiments, the present disclosure may provide (e.g., via substantially fully autonomous) auto-fault recovery (e.g., to prevent dusting) that may include one or more of pressure switch tripping, mass flow controller (MFC) flow verification (e.g., fluid calculation, fluid verification), recipe fault while fluid (e.g., precursor, oxidizer) flowing, macro faulting, and/or recipe faulting. The present disclosure may provide one or more of control of radio frequency (RF) (e.g., disabling manual RF strike and defining boundary conditions to prevent arcing, equipment damage, etc.), control of additional facility equipment (e.g., all facility equipment, heat exchanger, pump, etc.), etc.

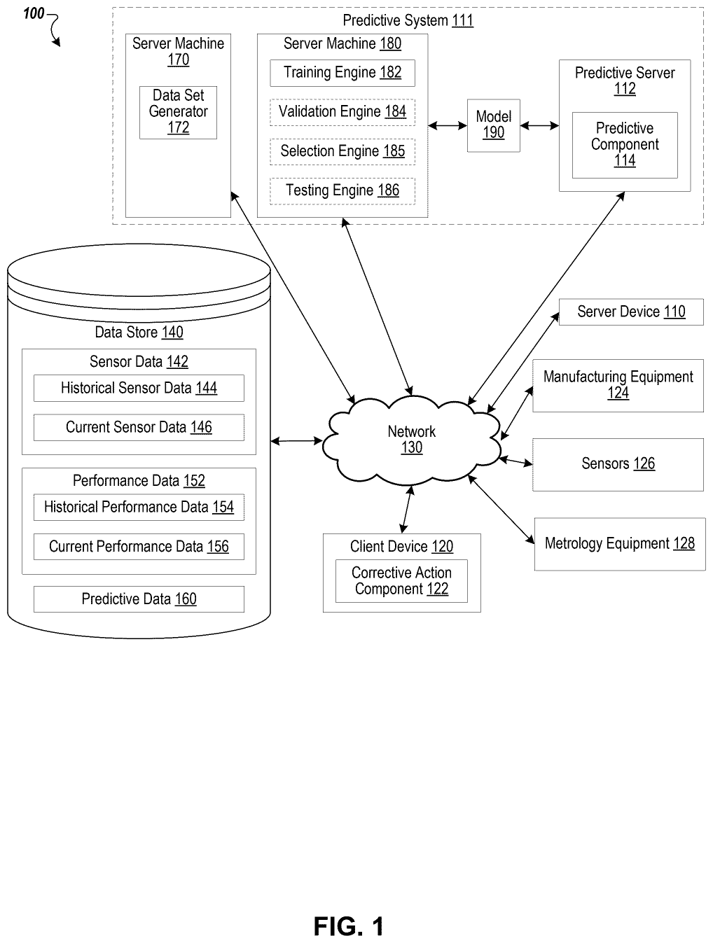

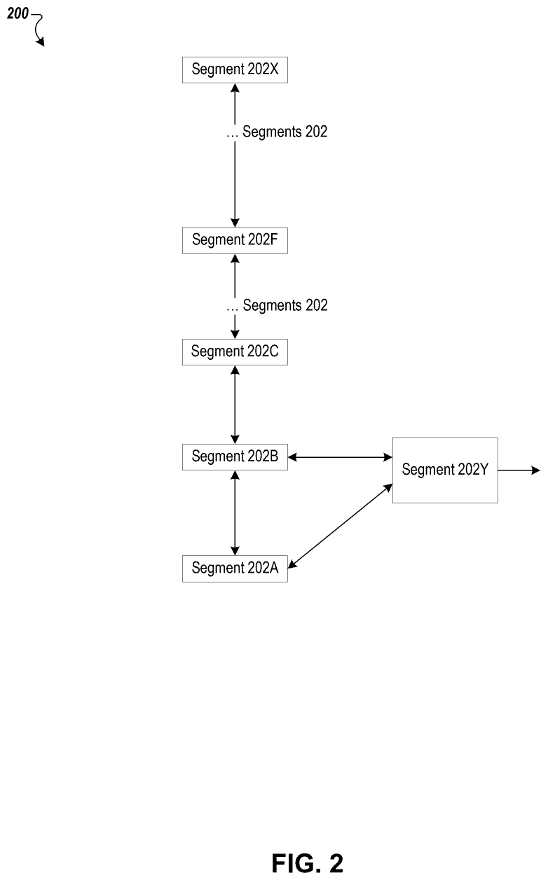

FIGS. 1-2 illustrate systems 100-200 associated with fail-safe control, according to certain embodiments.

FIG. 1 is a block diagram illustrating an exemplary system 100 (exemplary system architecture), according to certain embodiments. The system 100 includes server device 110, client device 120, manufacturing equipment 124, sensors 126, metrology equipment 128, a predictive server 112, and a data store 140. In some embodiments, the predictive server 112 is part of a predictive system 111. In some embodiments, the predictive system 111 further includes server machines 170 and 180.

In some embodiments, one or more of the server device 110, client device 120, manufacturing equipment 124, sensors 126, metrology equipment 128, predictive server 112, server machine 170, server machine 180, and/or data store 140 are coupled to each other via a network 130 for performing one or more methods of the present disclosure. In some embodiments, network 130 is a public network that provides client device 120 with access to the server device 110, predictive server 112, data store 140, and other publicly available computing devices. In some embodiments, network 130 is a private network that provides client device 120 access to manufacturing equipment 124, sensors 126, metrology equipment 128, data store 140, and other privately available computing devices. In some embodiments, network 130 includes one or more Wide Area Networks (WANs), Local Area Networks (LANs), wired networks (e.g., Ethernet network), wireless networks (e.g., an 802.11 network or a Wi-Fi network), cellular networks (e.g., a Long Term Evolution (LTE) network), routers, hubs, switches, server computers, cloud computing networks, and/or a combination thereof.

In some embodiments, the client device 120 includes a computing device such as Personal Computers (PCs), laptops, mobile phones, smart phones, tablet computers, netbook computers, etc.

In some embodiments, the server device 110, predictive server 112, server machine 170, and/or server machine 180 each includes one or more computing devices such as a rackmount server, a router computer, a server computer, a personal computer, a mainframe computer, a laptop computer, a tablet computer, a desktop computer, Graphics Processing Unit (GPU), accelerator Application-Specific Integrated Circuit (ASIC) (e.g., Tensor Processing Unit (TPU)), etc.

The predictive server 112 includes a predictive component 114. In some embodiments, the predictive component 114 receives sensor data 142 (e.g., from the client device 120, retrieves from the data store 140) and generates predictive data 160 associated with one or more of the methods of the present disclosure (e.g., causing fail-safe control in substrate processing systems, causing substrate processing). In some embodiments, the predictive component 114 uses one or more trained machine learning models 190 to determine the predictive data 160. In some embodiments, trained machine learning model 190 is trained using historical sensor data 144 and historical performance data 154.

In some embodiments, the predictive system 111 (e.g., predictive server 112, predictive component 114) generates predictive data 160 using supervised machine learning (e.g., supervised data set, historical sensor data 144 labeled with historical performance data 154, etc.). In some embodiments, the predictive system 111 generates predictive data 160 using semi-supervised learning (e.g., historical sensor data 144 is of normal substrate runs, semi-supervised data set, performance data 152 is a predictive percentage, etc.). In some embodiments, the predictive system 111 generates predictive data 160 using unsupervised machine learning (e.g., unsupervised data set, clustering, clustering based on historical sensor data 144, etc.).

In some embodiments, the manufacturing equipment 124 (e.g., cluster tool) is part of a substrate processing system (e.g., integrated processing system). The manufacturing equipment 124 includes one or more of a controller, an enclosure system (e.g., substrate carrier, front opening unified pod (FOUP), auto teach FOUP, process kit enclosure system, substrate enclosure system, cassette, etc.), a side storage pod (SSP), an aligner device (e.g., aligner chamber), a factory interface (e.g., equipment front end module (EFEM)), a load lock, a transfer chamber, one or more processing chambers (e.g., that produce plasma, multi-slot processing chambers), a robot arm (e.g., disposed in the transfer chamber, disposed in the front interface, etc.), and/or the like. The enclosure system, SSP, and load lock mount to the factory interface and a robot arm disposed in the factory interface is to transfer content (e.g., substrates, process kit rings, carriers, validation wafer, etc.) between the enclosure system, SSP, load lock, and factory interface. The aligner device is disposed in the factory interface to align the content. The load lock and the processing chambers mount to the transfer chamber and a robot arm disposed in the transfer chamber is to transfer content (e.g., substrates, process kit rings, carriers, validation wafer, etc.) between the load lock, the processing chambers, and the transfer chamber. In some embodiments, the manufacturing equipment 124 includes components of substrate processing systems. In some embodiments, data store 140 includes sensor data including parameters of processes performed by components of the manufacturing equipment 124 (e.g., RF generation, lifting, etching, heating, cooling, transferring, processing, flowing, cleaning, etc.).

In some embodiments, the sensors 126 provide sensor data (e.g., sensor values, such as historical sensor values and current sensor values) associated with manufacturing equipment 124. In some embodiments, the sensors 126 include one or more of a power sensor, a flow rate sensor, a thermal sensor, RF sensor, a lift sensor, an imaging sensor (e.g., camera, image capturing device, etc.), a pressure sensor, a temperature sensor, a flow rate sensor, a spectroscopy sensor, and/or the like. In some embodiments, the sensor data used for equipment health and/or product health (e.g., product quality). In some embodiments, the sensor data is received over a period of time. In some embodiments, sensors 126 provide sensor data such as values of one or more of power data, temperature data, fluid flow rate data, mass flow rate data, specific heat data, temperature difference, thermal stress data, flow rate ratio data, image data, leak rate, temperature, pressure, flow rate (e.g., fluid flow), pumping efficiency, spacing (SP), High Frequency Radio Frequency (HFRF), electrical current, power, voltage, and/or the like. In some embodiments, the sensor data 142 and/or performance data 152 includes sensor data from one or more of sensors 126.

In some embodiments, the sensor data 142 (e.g., historical sensor data 144, current sensor data 146, etc.) is processed by the client device 120, predictive server 112, and/or by the server device 110. In some embodiments, processing of the sensor data includes generating features. In some embodiments, the features are a portion of the sensor data (e.g., transfer operations, processing operations, etc.), processed sensor data (e.g., processed transfer data, processed processing data), pattern in the sensor data (e.g., repetition of transfers, processing, etc.), or a combination of values from the sensor data (e.g., ratio of transfer time to processing time, etc.). In some embodiments, the sensor data includes features that are used by the server device 110 and/or client device 120 to perform one or more of the methods of the present disclosure.

In some embodiments, the metrology equipment 128 (e.g., imaging equipment, spectroscopy equipment, ellipsometry equipment, etc.) is used to determine metrology data (e.g., inspection data, image data, spectroscopy data, ellipsometry data, material compositional, optical, or structural data, etc.) corresponding to substrates produced by the manufacturing equipment 124 (e.g., substrate processing equipment). In some examples, after the manufacturing equipment 124 processes substrates, the metrology equipment 128 is used to inspect portions (e.g., layers) of the substrates. In some embodiments, the metrology equipment 128 performs scanning acoustic microscopy (SAM), ultrasonic inspection, x-ray inspection, and/or computed tomography (CT) inspection. In some examples, after the manufacturing equipment 124 deposits one or more layers on a substrate, the metrology equipment 128 is used to determine quality of the processed substrate (e.g., thicknesses of the layers, uniformity of the layers, interlayer spacing of the layer, and/or the like). In some embodiments, the metrology equipment 128 includes an image capturing device (e.g., SAM equipment, ultrasonic equipment, x-ray equipment, CT equipment, and/or the like). In some embodiments, data store 140 stores performance data 152 (e.g., metrology data) from metrology equipment 128.

In some embodiments, the data store 140 is memory (e.g., random access memory), a drive (e.g., a hard drive, a flash drive), a database system, or another type of component or device capable of storing data. In some embodiments, data store 140 includes multiple storage components (e.g., multiple drives or multiple databases) that span multiple computing devices (e.g., multiple server computers). In some embodiments, the data store 140 stores one or more of sensor data 142, performance data 152, and/or predictive data 160.

Sensor data 142 includes historical sensor data 144 and current sensor data 146. In some embodiments, sensor data 142 may include one or more of pressure data, flow rate data, power data, temperature data, fluid flow rate data, mass flow rate data, specific heat data, temperature difference, thermal stress data, flow rate ratio data, etc. In some embodiments, at least a portion of the sensor data 142 is from client device 120, data store 140, and/or sensors 126.

Performance data 152 includes historical performance data 154 and current performance data 156. In some embodiments, at least a portion of the performance data 152 is associated with sections (e.g., piping, valves, chambers, etc.) of the substrate processing system. In some embodiments, at least a portion of the performance data 152 is associated with whether property data of substrates meets threshold property data (e.g., whether the substrates are good substrates, whether the substrates are from normal substrate runs). The performance data 152 may include whether the one or more substrates are faulty. Performance data 152 may include property values of a substrate, an indication of whether property values of a substrate meet threshold values, etc. In some examples, the performance data 152 is indicative of whether a substrate is properly produced, and/or properly functioning. In some embodiments, at least a portion of the performance data 152 is associated with a quality of substrates produced by the manufacturing equipment 124. In some embodiments, at least a portion of the performance data 152 is based on metrology data from the metrology equipment 128 (e.g., historical performance data 154 includes metrology data indicating properly processed substrates, property data of substrates, yield, etc.). In some embodiments, at least a portion of the performance data 152 is based on inspection of the substrates (e.g., current performance data 156 based on actual inspection). In some embodiments, the performance data 152 includes an indication of an absolute value (e.g., inspection data of the bond interfaces indicates missing the threshold data by a calculated value, deformation value misses the threshold deformation value by a calculated value) or a relative value (e.g., inspection data of the bond interfaces indicates missing the threshold data by 5%, deformation misses threshold deformation by 5%). In some embodiments, the performance data 152 is indicative of meeting a threshold amount of error (e.g., at least 5% error in production, at least 5% error in flow, at least 5% error in deformation, specification limit).

In some embodiments, the client device 120 provides performance data 152. In some examples, the client device 120 provides (e.g., based on user input) performance data 152 that indicates an abnormality in substrates (e.g., defective substrates). In some embodiments, the performance data 152 includes an amount of substrates that have been produced that were normal or abnormal (e.g., 98% normal substrates). In some embodiments, the performance data 152 indicates an amount of substrates that are being produced that are predicted as normal or abnormal. In some embodiments, the performance data 152 includes one or more of yield a previous batch of substrates, average yield, predicted yield, predicted amount of defective or non-defective product, or the like. In some examples, responsive to yield on a first batch of substrates being 98% (e.g., 98% of the substrates were normal and 2% were abnormal), the client device 120 provides performance data 152 indicating that the upcoming batch of substrates is to have a yield of 98%.

In some embodiments, historical data includes one or more of historical sensor data 144 and/or historical performance data 154 (e.g., at least a portion for training the machine learning model 190). Current data includes one or more of current sensor data 146 and/or current performance data 156 (e.g., at least a portion to be input into the trained machine learning model 190 subsequent to training the model 190 using the historical data). In some embodiments, the current data is used for retraining the trained machine learning model 190.

In some embodiments, the predictive data 160 is to be used for fail-safe control in substrate processing systems (e.g., to cause substrate processing).

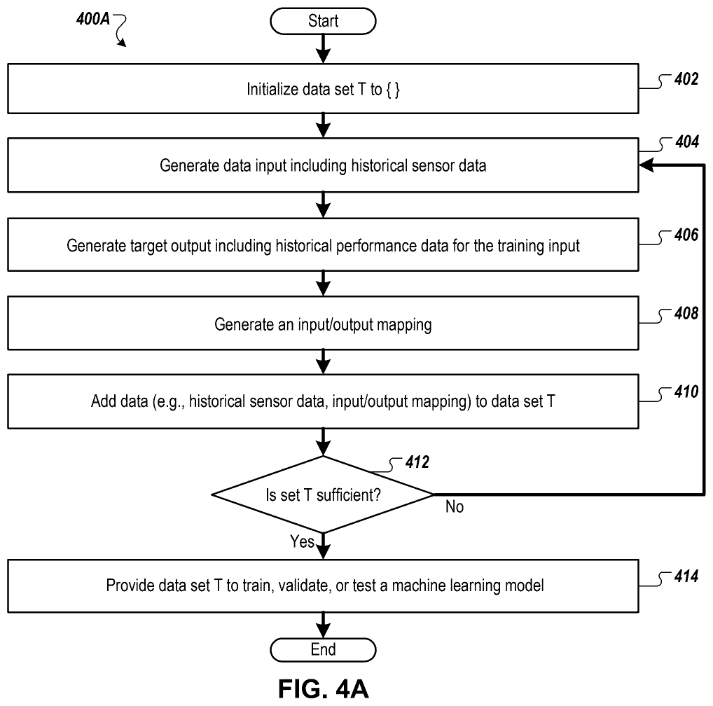

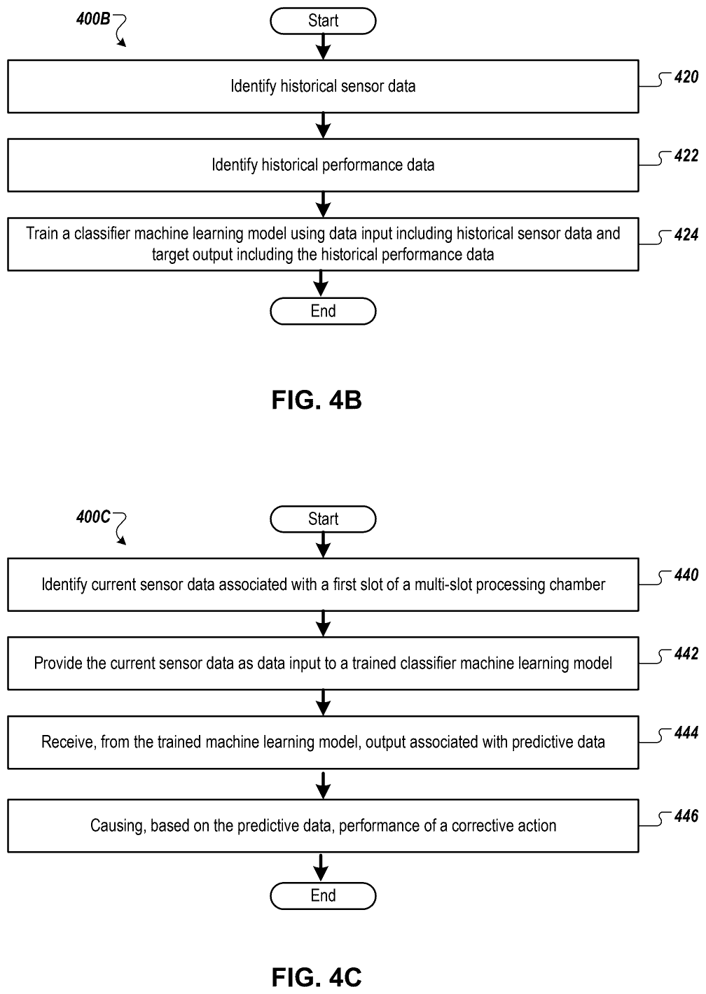

In some embodiments, predictive system 111 further includes server machine 170 and server machine 180. Server machine 170 includes a data set generator 172 that is capable of generating data sets (e.g., a set of data inputs and a set of target outputs) to train, validate, and/or test a machine learning model(s) 190. The data set generator 172 has functions of data gathering, compilation, reduction, and/or partitioning to put the data in a form for machine learning. In some embodiments (e.g., for small datasets), partitioning (e.g., explicit partitioning) for post-training validation is not used. Repeated cross-validation (e.g., 5-fold cross-validation, leave-one-out-cross-validation) may be used during training where a given dataset is in-effect repeatedly partitioned into different training and validation sets during training. A model (e.g., the best model, the model with the highest accuracy, etc.) is chosen from vectors of models over automatically-separated combinatoric subsets. In some embodiments, the data set generator 172 may explicitly partition the historical data (e.g., historical sensor data 144 and corresponding historical performance data 154) into a training set (e.g., sixty percent of the historical data), a validating set (e.g., twenty percent of the historical data), and a testing set (e.g., twenty percent of the historical data). In this embodiment, some operations of data set generator 172 are described in detail below with respect to FIG. 4A. In some embodiments, the predictive system 111 (e.g., via predictive component 114) generates multiple sets of features (e.g., training features). In some examples a first set of features corresponds to a first set of types of sensor data 142 (e.g., first types of operations, associated with a first set of sensors, first combination of values, first patterns in the values) that correspond to each of the data sets (e.g., training set, validation set, and testing set) and a second set of features correspond to a second set of types of sensor data 142 (e.g., second types of operations, associated with a second set of sensors different from the first set of sensors, second combination of values different from the first combination, second patterns different from the first patterns) that correspond to each of the data sets.

Server machine 180 includes a training engine 182, a validation engine 184, selection engine 185, and/or a testing engine 186. In some embodiments, an engine (e.g., training engine 182, a validation engine 184, selection engine 185, and a testing engine 186) refers to hardware (e.g., circuitry, dedicated logic, programmable logic, microcode, processing device, etc.), software (such as instructions run on a processing device, a general purpose computer system, or a dedicated machine), firmware, microcode, or a combination thereof. The training engine 182 is capable of training a machine learning model 190 using one or more sets of features associated with the training set from data set generator 172. In some embodiments, the training engine 182 generates multiple trained machine learning models 190, where each trained machine learning model 190 corresponds to a distinct set of parameters of the training set (e.g., sensor data 142) and corresponding responses (e.g., performance data 152). In some embodiments, multiple models are trained on the same parameters with distinct targets for the purpose of modeling multiple effects. In some examples, a first trained machine learning model was trained using sensor data 142 for all operations (e.g., operations 1-5), a second trained machine learning model was trained using a first subset of the sensor data 142 (e.g., operations 1, 2, and 4), and a third trained machine learning model was trained using a second subset of the sensor data 142 (e.g., operations 1, 3, 4, and 5) that partially overlaps the first subset of features.

The validation engine 184 is capable of validating a trained machine learning model 190 using a corresponding set of features of the validation set from data set generator 172. For example, a first trained machine learning model 190 that was trained using a first set of features of the training set is validated using the first set of features of the validation set. The validation engine 184 determines an accuracy of each of the trained machine learning models 190 based on the corresponding sets of features of the validation set. The validation engine 184 evaluates and flags (e.g., to be discarded) trained machine learning models 190 that have an accuracy that does not meet a threshold accuracy. In some embodiments, the selection engine 185 is capable of selecting one or more trained machine learning models 190 that have an accuracy that meets a threshold accuracy. In some embodiments, the selection engine 185 is capable of selecting the trained machine learning model 190 that has the highest accuracy of the trained machine learning models 190.

The testing engine 186 is capable of testing a trained machine learning model 190 using a corresponding set of features of a testing set from data set generator 172. For example, a first trained machine learning model 190 that was trained using a first set of features of the training set is tested using the first set of features of the testing set. The testing engine 186 determines a trained machine learning model 190 that has the highest accuracy of all of the trained machine learning models based on the testing sets.

In some embodiments, the machine learning model 190 (e.g., used for classification) refers to a model artifact that is created by the training engine 182 using a training set that includes data inputs and corresponding target outputs (e.g., correctly classifies a condition or ordinal level for respective training inputs). Patterns in the data sets can be found that map the data input to the target output (the correct classification or level), and the machine learning model 190 is provided mappings that captures these patterns. In some embodiments, the machine learning model 190 uses one or more of Gaussian Process Regression (GPR), Gaussian Process Classification (GPC), Bayesian Neural Networks, Neural Network Gaussian Processes, Deep Belief Network, Gaussian Mixture Model, or other Probabilistic Learning methods. Non probabilistic methods may also be used including one or more of Support Vector Machine (SVM), Radial Basis Function (RBF), clustering, Nearest Neighbor algorithm (k-NN), linear regression, random forest, neural network (e.g., artificial neural network), etc. In some embodiments, the machine learning model 190 is a multi-variate analysis (MVA) regression model.

Predictive component 114 provides current sensor data 146 (e.g., as input) to the trained machine learning model 190 and runs the trained machine learning model 190 (e.g., on the input to obtain one or more outputs). The predictive component 114 is capable of determining (e.g., extracting) predictive data 160 from the trained machine learning model 190 and determines (e.g., extracts) uncertainty data that indicates a level of credibility that the predictive data 160 corresponds to current performance data 156. In some embodiments, the predictive component 114 or corrective action component 122 use the uncertainty data (e.g., uncertainty function or acquisition function derived from uncertainty function) to decide whether to use the predictive data 160 to perform a corrective action (e.g., interrupt operation of one or more components) or whether to further train the model 190.

For purpose of illustration, rather than limitation, aspects of the disclosure describe the training of one or more machine learning models 190 using historical data (i.e., prior data, historical sensor data 144 and historical performance data 154) and providing current sensor data 146 into the one or more trained probabilistic machine learning models 190 to determine predictive data 160. In other implementations, a heuristic model or rule-based model is used to determine predictive data 160 (e.g., without using a trained machine learning model). In other implementations non-probabilistic machine learning models may be used. Predictive component 114 monitors historical sensor data 144 and historical performance data 154.

In some embodiments, the functions of client device 120, predictive server 112, server machine 170, and server machine 180 are be provided by a fewer number of machines. For example, in some embodiments, server machine 170 and server machine 180 are integrated into a single machine, while in some other embodiments, server machine 170, server machine 180, and predictive server 112 are integrated into a single machine. In some embodiments, client device 120, server device 110, and/or predictive server 112 are integrated into a single machine.

In general, functions described in one embodiment as being performed by client device 120, predictive server 112, server machine 170, and server machine 180 can also be performed on predictive server 112 in other embodiments, if appropriate. In addition, the functionality attributed to a particular component can be performed by different or multiple components operating together. For example, in some embodiments, the predictive server 112 determines corrective actions based on the predictive data 160. In another example, client device 120 determines the predictive data 160 based on data received from the trained machine learning model.

In addition, the functions of a particular component can be performed by different or multiple components operating together. In some embodiments, one or more of the server device 110, predictive server 112, server machine 170, server machine 180, or client device 120 are accessed as a service provided to other systems or devices through appropriate application programming interfaces (API).

In some embodiments, a “user” is represented as a single individual. However, other embodiments of the disclosure encompass a “user” being an entity controlled by a plurality of users and/or an automated source. In some examples, a set of individual users federated as a group of administrators is considered a “user.”

Although embodiments of the disclosure are discussed in terms of fail-safe control in substrate processing systems, in some embodiments, the disclosure can also be generally applied to fail-safe control. Embodiments can be generally applied to controlling systems.

System 100 may be associated with fail-safe control, according to certain embodiments.

System 100 may provide positional awareness.

In some embodiments, system 100 provides positional awareness by portion (e.g., segment, piping, valves, etc.) of the substrate processing system (e.g., manufacturing equipment 124). This may be using a classification table by co-flow restrictions by segments and/or by using a class-table by MFC fluid controls. This may be by tying fluid number compatibility to allow co-flow or disallow by segment. For example, a first fluid may not co-exist or co-flow with a second fluid in multiple portions (e.g., segments) of the substrate processing system (e.g., manufacturing equipment 124). System 100 may not allow to configure the first fluid since the first fluid would share a segment with a second fluid.

System 100 may use a segment-timer-status interlock method. System 100 may bucket all valves actual location by segment-location. This may be by creating a real-time visual dashboard indicating which fluids are wetting which segments in the graphical user interface (e.g., may display timers and status of each segment). System 100 may provide all segment timer and status tracking (e.g., idle for a threshold amount of time). For example, at a threshold amount of time, a portion (e.g., segment, piping, valves) of the substrate processing system (e.g., manufacturing equipment 124) may be approved to divert responsive to volume NC (dry) from previous pump out. At a second threshold amount of time, the status of the portion of the substrate processing system may turn to NG—air/moisture ingress.

System 100 may have software command by manual or recipe at any time after a timer expires. The software may not allow fluid (e.g., precursor, oxidizer) flow to a portion of the substrate processing system. System 100 may notify the reason and may prompt for remedial action (e.g., cause a corrective action).

In some embodiments, processing logic may interrupt diverting of fluid (e.g., precursor, oxidizer) flow to a portion of the substrate processing system based on presence of moisture/air on path for pyrophoric fluid flow. Processing logic may cause a corrective action (e.g., prompt user input of conducting a remedial action). The corrective action may include closing the chamber iso-valve, pumping for a threshold amount of time, and/or performing a purging operation.

System 100 may have a segment-timer-status interlock method. System 100 may bucket all valves actual location by segment-location. System 100 may create a real-time visual dashboard indicating which fluids are wetting which segments in the graphical user interface. All segments may have timers, status, and action tracking. Fluid (e.g., precursor, oxidizer) may flow to chamber and fills all NO segments.

In some embodiments, first fluid (e.g., precursor, oxidizer) is commanded to stop, residual fluid (e.g., precursor, oxidizer) may still be in NO volumes.

System 100 may prevent second fluid flow. System 100 may notify and may cause a corrective action (e.g., an option of a remedial action).

In some examples, system 100 may have a first operation of pumping, a second operation of purging, and a third operation of final pump.

In some embodiments, processing logic may disable second fluid flow (e.g., manual second fluid flow) to the chamber responsive to determining presence of residual first fluid (e.g., precursor, oxidizer, pyrophoric fluid) in one or more segments of the path for the first fluid. Processing logic may cause a corrective action (e.g., prompt user input of conducting a remedial action). The corrective action may include pumping segments for a threshold amount of time, purging the segments for a threshold amount of time, and performing a final pump of the segments for a threshold amount of time.

FIG. 2 illustrates a system 200 (e.g., substrate processing system, manufacturing equipment 124) associated with fail-safe control. System 200 may have different segments 202 (e.g., portions of substrate processing system). The area location and features (e.g., significance) of each segment 202 may be defined. Segment states may be partially defined by when a specific fluid is in a segment 202 (e.g., fully charged, residual, or dry). Flow of fluids in system 200 may depend on the class of the fluid (e.g., gas, liquid, precursor, oxidizer, etc.) previously present in a segment 202 (e.g., immediately prior to a new fluid) and the new fluid that is to be flowed into the segment 202. Compatibility of fluids co-existing may be determined to cause flowing of fluids. Pre-determined mitigation that is to be used to flow fluids sequentially in actions related to type of fluid may be determined.

Segments 202 may be one or more of a fluid panel, transport lines (e.g., piping) to chamber, lid manifold with valve (e.g., fluid mixing), post-manifold mixing fluid lines, divert fluid lines and manifold, chamber cavity, and/or exhaust lines to pump.

The present disclosure may track one or more fluids present in each segment 202.

The present disclosure may have times for each segment 202 when fluid is in a segment 202 (e.g., fluid fill wet areas). How long one or more specific fluids are present in the segment 202 and how long since a fluid was previously in the segment 202 may be used to determine if a next fluid coming into the segment 202 is compatible based on fluid classification and corresponding rules and action table.

The present disclosure may have a tracker of time and state which maps to a rule table for various fluid classes. A processing device of the present disclosure may allow or prevent fluid flow based on the tracker of time and state and the rule table for the various fluid classes.

In some embodiments, the present disclosure provides positional awareness of valves and fluid delivery components (e.g., all valves and gas delivery components). The present disclosure may provide system-chamber segmentation (e.g., portions of the substrate processing system). The present disclosure may provide visual representation of fluid wetted area by segments 202. The present disclosure may be used to track presence of each fluid present in each segment 202 and interaction rules for each other fluid being introduced. The present disclosure may classify fluids (e.g., as pyrophoric, toxic, oxidizer, toxic oxidizer, non-reactive oxidizer, corrosive, liquid, gas, etc.). The classification of the fluids may be used to determine one or more of co-flow requirements, sequential flow, cycle purge, minimum inert purge, and/or minimum pump.

The present disclosure may have timers for each segment 202 when fluids fill wet areas. The present disclosure may provide a visual simulator for new recipes created on wetted zones (e.g., segments 202). The present disclosure may assist recipe creation based on impact of fluid distribution and dead volumes.

In some embodiments, a processing device may define area location of each segment 202 (e.g., segment 202A and segment 202F) and significance (e.g., when and what type of fluid flowed through a particular segment 202). A processing device may determine fluid type (e.g., SiH4, pyrophoric), a timer (e.g., time each fluid is present in a segment 202), and a status of the segment 202 (e.g., charged, residual, dry, etc.). In some embodiments, subsequent to segment 202A providing fluid to X, segment 202B is to provide fluid to 202Y (e.g., watch dog zone of whetted gas mixture, processing chamber, etc.). The processing device is to determine the fluid type, timer, and status of segment 202Y following fluid flow from segment 202A and may cause a corrective action prior to providing fluid flow from segment 202B to segment 202Y.

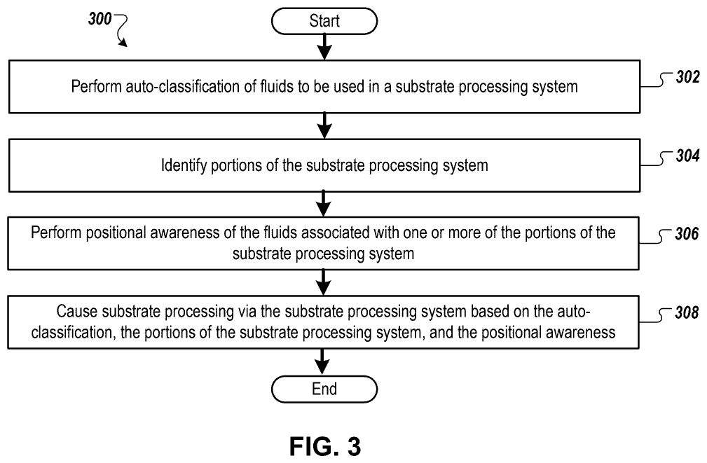

FIGS. 3-4C illustrate flow diagrams of method 300-400C associated with fail-safe control, according to certain embodiments. In some embodiments, one or more of methods 300-400C is performed by processing logic that includes hardware (e.g., circuitry, dedicated logic, programmable logic, microcode, processing device, etc.), software (such as instructions run on a processing device, a general purpose computer system, or a dedicated machine), firmware, microcode, or a combination thereof. In some embodiments, one or more of methods 300-400C is performed, at least in part, by server device 110, predictive server 112, and/or client device 120 of FIG. 1. In some embodiments, method 400A is performed, at least in part, by predictive system 111 (e.g., server machine 170 and data set generator 172 of FIG. 1). In some embodiments, predictive system 111 uses method 400A to generate a data set to at least one of train, validate, or test a machine learning model. In some embodiments, method 400B is performed by server machine 180 (e.g., training engine 182, etc.). In some embodiments, method 400C is performed by predictive server 112 (e.g., predictive component 114). In some embodiments, a non-transitory storage medium stores instructions that when executed by a processing device (e.g., of server device 110, of client device 120, etc.), cause the processing device to perform one or more of methods 300-400C.

For simplicity of explanation, methods 300-400C are depicted and described as series of operations. However, operations in accordance with this disclosure can occur in various orders and/or concurrently and with other operations not presented and described herein. Furthermore, in some embodiments, not all illustrated operations are performed to implement methods 300-400C in accordance with the disclosed subject matter. In addition, those skilled in the art will understand and appreciate that each of methods 300-400C could alternatively be represented as a series of interrelated states via a state diagram or events.

Referring to FIG. 3, in some embodiments, at block 302 the processing logic implementing method 300 performs auto-classification of fluids to be used in a substrate processing system. The processing logic may receive a recipe. The processing logic may determine the fluids used in the recipe. The processing logic may determine which fluids are an inert fluid, a reactive oxidizing fluid, a non-reactive oxidizing fluid, and/or a corrosive fluid.

At block 304, processing logic identifies portions (e.g., segments, piping, valves, etc.) of a substrate processing system (e.g., identify various parts or segments of the substrate processing system). The processing logic may determine that particular piping, valves, manifolds, etc. are between a fluid supply and a chamber (e.g., processing chamber, etc.).

At block 306, processing logic performs positional awareness of the fluids associated with one or more of the portions of the substrate processing system (e.g., identifying the portions of the substrate processing system where the fluids are located).

At block 308, processing logic causes substrate processing via substrate processing equipment based on the auto-classification, the portions of the substrate processing system, and the positional awareness. The causing of substrate processing may include causing a flushing (e.g., purging) of a portion of the substrate processing system and then causing a fluid to pass through the portion of the substrate processing system. In some embodiments, the processing logic provides data input (e.g., sensor data) associated with one or more of the auto-classification, the portions of the substrate processing system, and/or the positional awareness as input to a trained machine learning model and causes the substrate processing based on output (e.g., predictive data) from the trained machine learning model.

In some embodiments, the present disclosure reduces or eliminates unwanted reactions between incompatible process chemicals.

Many complex manufacturing processes use the sequential use of incompatible process chemicals within the same processing system or tool. Although systems may have complex systems of interlocks and procedural safeguards to prevent simultaneous introduction of incompatible chemicals such as silane and oxygen into a processing volume (or chamber) when the tool is operating in a production setting, it is still not uncommon for process chambers or tools to fail due to unwanted chemical reactions between incompatible process chemicals. Furthermore, the situation is much less controlled when the processing chamber or tool is taken offline into a manual maintenance mode during scheduled maintenance or when in recovery mode after an unscheduled chamber fault. At such times, control of the chamber may depend (e.g., be entirely dependent) on operator skill and experience which can vary widely and can be prone to operator error.

In addition, an even lower level of care and awareness is usually practiced in other portions of the process system either upstream or downstream of the substrate processing chamber volume. These areas include what is commonly referred to as the gas panel and the network of various upstream chemical delivery lines, the exhaust lines exiting the process chamber, and even down to the chamber and tool pumps. Conventional substrate processing tool control systems do not typically account for the interactions of the various portions of the tool due to system complexity and a past failure to recognize that sensitivity to impacts from unwanted interactions between incompatible process chemicals anywhere within the processing system. This is becoming increasingly more critical for acceptable processing and device performance at advanced technology nodes.

One conventional source of error is introduction of a highly reactive gas, such as silane, into a volume which has residual levels of incompatible chemicals such as oxygen. For example, without allowing for the proper procedures (e.g., adequate pumping and purging) to be followed to remove residual oxygen from various portions of the processing system, silane introduced into the previously oxygen-exposed volumes interacts with the residual oxygen and create solid residues that can form a fine dust. These residues can result in system and substrate contamination and subsequent unscheduled downtime to remediate and recover the processing system.

Due to the complex nature of typical substrate processing systems (e.g., with their many potential chemical delivery paths, valving, and possible mixing points) reliance on operator skill to configure the system or to perform post-fault recovery can lead to inconsistent results due to differing experience levels and human error.

In some embodiments, the present disclosure (e.g., processing logic, processing device, one or more of methods 300-400C, system 100, system 200, etc.) classifies all chemicals used in the processing tool and segments the substrate processing tool into distinct modules with characteristic properties (e.g., volume, surface area, temperature, and operating pressure). In addition, the present disclosure (e.g., processing logic, processing device, one or more of methods 300-400C, system 100, system 200, etc.) keeps track of which chemicals were previously located in each segment, the time since those chemicals were in each segment, the chemicals currently in each segment, and the chemicals to introduce (e.g., a user would like to introduce) into each segment (e.g., by looking ahead in an automated process recipe programmed by a user). Using chemical class and system segment specific rules, the present disclosure (e.g., processing logic, processing device, one or more of methods 300-400C, system 100, system 200, etc.) can provide an alert (e.g., alert the user) to potential unwanted interactions between incompatible chemicals, suspend tool operation, and provide instructions (e.g., guide the user through) or cause a corrective action (e.g., automatically implement) associated with needed fault avoidance or remediation and recovery steps before resuming normal tool operation.

In some embodiments, the present disclosure is an adaptive system controller that uses artificial intelligence (AI) and/or machine learning (e.g., system sentry framework).

Inputs to the system sentry can include sensor data (e.g., pressure data, etc.) on component and chamber (tool) equipment states and software inputs controlling equipment states and process conditions and parameters. Incorporation of machine learning and artificial intelligence applied to sensor data and feedback from both in situ and ex situ measurements of process performance (e.g., deposited film properties, process rate, uniformity, defectivity, device yield) can be used to modify the corrective actions used by the system sentry to accommodate potential shifts in chamber condition and/or response to process inputs. For example, based on changing chamber performance as measured by particle defect counts and characterization measured on processed wafers, the rules (e.g., system sentry rules) on gas line purging between introduction of certain incompatible process gases into a common section of the gas delivery system can be modified to avoid unscheduled chamber maintenance.

In some embodiments, the present disclosure provides intelligent design aid for process and equipment design.

The present disclosure (e.g., processing logic, processing device, one or more of methods 300-400C, system 100, system 200, etc.) can be used to check proposed automated process recipes (or sequences) for potential errors in the process design stage. Additionally, the present disclosure (e.g., processing logic, processing device, one or more of methods 300-400C, system 100, system 200, etc.) can be used to check proposed equipment designs for potential pitfalls when simulating known process recipes. In both cases, the sentry system can be used as an intelligent design aid in the development of both process recipes and equipment design.

In some embodiments, the present disclosure is applied to other areas other than prevention of unwanted chemical interactions.

Although some embodiments of the present disclosure are directed towards the prevention of unwanted reactions between incompatible process chemicals and the resulting equipment damage or negative substrate processing quality impacts, in some embodiments the present disclosure can be used to prevent other undesirable situations within the processing system. Examples include prevention of potential negative process outcomes or equipment damage from unwanted process sequences involving RF plasma, temperature and vacuum controls, and/or substrate handling and placement. FIG. 4A is a flow diagram of a method 400A for generating a data set for a machine learning model for generating predictive data (e.g., predictive data 160 of FIG. 1) associated with fail-safe control, according to certain embodiments.

Referring to FIG. 4A, in some embodiments, at block 402 the processing logic implementing method 400A initializes a training set T to an empty set.

At block 404, processing logic generates first data input (e.g., first training input, first validating input) that includes historical sensor data (e.g., historical sensor data 144 of FIG. 1, pressure data, data associated with the segments of the substrate processing system, etc.). In some embodiments, the first data input includes a first set of features for types of sensor data and a second data input includes a second set of features for types of sensor data.

In some embodiments, at block 406, processing logic generates a first target output for one or more of the data inputs (e.g., first data input). In some embodiments, the first target output is historical performance data (e.g., historical performance data 154 of FIG. 1, property data of substrate processed by the substrate processing system, property data of the segments of the substrate processing system, etc.).

In some embodiments, at block 408, processing logic optionally generates mapping data that is indicative of an input/output mapping. The input/output mapping (or mapping data) refers to the data input (e.g., one or more of the data inputs described herein), the target output for the data input (e.g., where the target output identifies historical performance data 154), and an association between the data input(s) and the target output.

At block 410, processing logic adds the data (e.g., historical sensor data from block 404, mapping data generated at block 408) to data set T.

At block 412, processing logic branches based on whether data set T is sufficient for at least one of training, validating, and/or testing machine learning model 190 (e.g., uncertainty of the trained machine learning model meets a threshold uncertainty). If so, execution proceeds to block 414, otherwise, execution continues back to block 404. It should be noted that in some embodiments, the sufficiency of data set T is determined based simply on the number of input/output mappings in the data set, while in some other implementations, the sufficiency of data set T is determined based on one or more other criteria (e.g., a measure of diversity of the data examples, accuracy, etc.) in addition to, or instead of, the number of input/output mappings.

At block 414, processing logic provides data set T (e.g., to server machine 180) to train, validate, and/or test machine learning model 190. In some embodiments, data set T is a training set and is provided to training engine 182 of server machine 180 to perform the training. In some embodiments, data set T is a validation set and is provided to validation engine 184 of server machine 180 to perform the validating. In some embodiments, data set T is a testing set and is provided to testing engine 186 of server machine 180 to perform the testing. In the case of a neural network, for example, input values of a given input/output mapping (e.g., numerical values associated with data inputs) are input to the neural network, and output values (e.g., numerical values associated with target outputs) of the input/output mapping are stored in the output nodes of the neural network. The connection weights in the neural network are then adjusted in accordance with a learning algorithm (e.g., back propagation, etc.), and the procedure is repeated for the other input/output mappings in data set T.

After block 414, machine learning model (e.g., machine learning model 190) can be at least one of trained using training engine 182 of server machine 180, validated using validating engine 184 of server machine 180, or tested using testing engine 186 of server machine 180. The trained machine learning model is implemented by predictive component 114 (of predictive server 112) to generate predictive data (e.g., predictive data 160) for fail-safe control in substrate processing systems.

FIG. 4B is a method 400B associated with fail-safe control in substrate processing systems, according to certain embodiments.

FIG. 4B is a method 400B for training a machine learning model (e.g., model 190 of FIG. 1) for determining predictive data (e.g., predictive data 160 of FIG. 1) associated with fail-safe control in substrate processing systems.

Referring to FIG. 4B, at block 420 of method 400B, the processing logic identifies historical sensor data (e.g., historical sensor data 144 of FIG. 1). In some embodiments, the historical sensor data includes one or more of historical pressure data, historical temperature data, historical flow rate data, etc. associated with segments of a substrate processing system. In some embodiments, the historical sensor data includes when a type of fluid was in a portion of the substrate processing system. In some embodiments, the historical sensor data includes when fluid supplies and/or valves allowed types of fluids to enter portions of the substrate processing system.

At block 422, the processing logic identifies historical performance data (e.g., historical performance data 154 of FIG. 1). In some embodiments, the historical performance data is associated with quality of substrates (e.g., metrology data) produced using the historical sensor data. In some embodiments, the historical performance data is indicative of whether one or more components are malfunctioning during the processing of the substrate during which the historical sensor data of block 420 is identified. In some embodiments, the historical performance data is associated with performance of segments of the substrate processing system.

At block 424, the processing logic trains a classifier machine learning model using data input including historical sensor data and target output including the historical performance data to generate a trained classifier machine learning model (e.g., configured to provide output associated with fail-safe control in substrate processing systems). The fail-safe control (e.g., to perform a corrective action) may be by using the trained classifier machine learning model of FIG. 4C. In some embodiments, the trained machine learning model is a neural network.

FIG. 4C is a method 400C for using a trained machine learning model (e.g., model 190 of FIG. 1) associated with fail-safe control in substrate processing systems. FIG. 4C may be used as part of method 300 (block 308) of FIG. 3.

Referring to FIG. 4C, at block 440 of method 400C, the processing logic identifies current sensor data. In some embodiments, the current sensor data includes one or more of current pressure data, current flow rate data, current temperature data, etc. In some embodiments, the current sensor data includes when a type of fluid was or is to be in a portion of the substrate processing system.

At block 442, the processing logic provides the current sensor data as data input to a trained classifier machine learning model (e.g., trained via block 424 of FIG. 4B).

At block 464, the processing logic receives, from the trained classifier machine learning model, output associated with predictive data (e.g., associated with fail- safe control in substrate processing systems). In some embodiments, the predictive data is associated with predicted performance data (e.g., whether substrates are to have defects, whether the substrate processing system is to have problems, etc.).

At block 466, the processing logic causes, based on the predictive data, substrate processing via the substrate processing system (e.g., block 308 of FIG. 3).

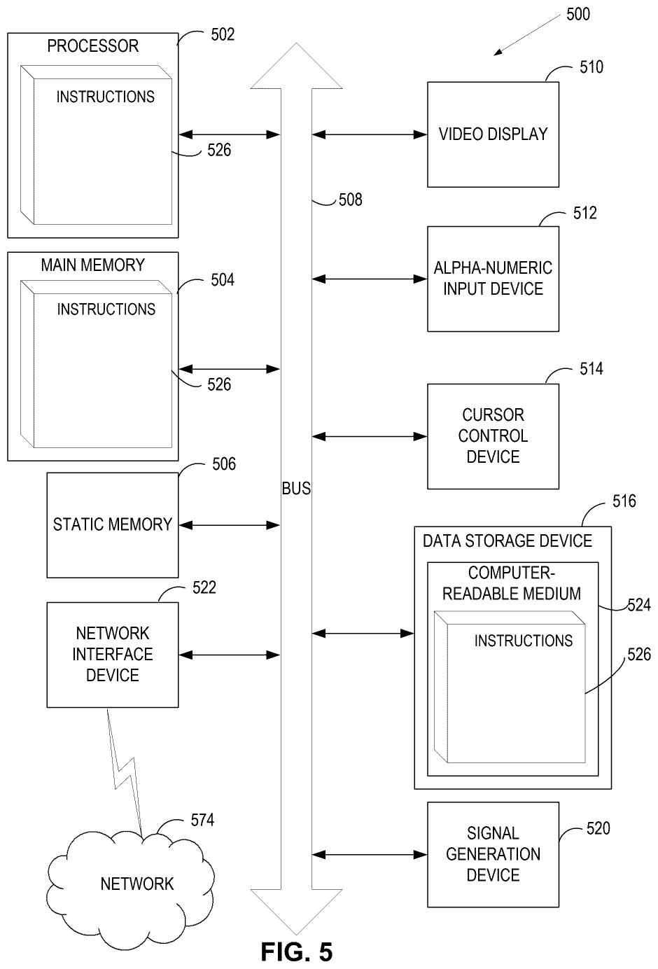

FIG. 5 is a block diagram illustrating a computer system 500, according to certain embodiments. In some embodiments, the computer system 500 is one or more of client device or server device. In some embodiments, the computer system 500 is one or more of client device 120, server device 110, server machine 170, server machine 180, and/or predictive server 112 of FIG. 1.

In some embodiments, computer system 500 is connected (e.g., via a network, such as a Local Area Network (LAN), an intranet, an extranet, or the Internet) to other computer systems. In some embodiments, computer system 500 operates in the capacity of a server or a client computer in a client-server environment, or as a peer computer in a peer-to-peer or distributed network environment. In some embodiments, computer system 500 is provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 500 includes a processing device 502, a volatile memory 504 (e.g., Random Access Memory (RAM)), a non-volatile memory 506 (e.g., Read-Only Memory (ROM) or Electrically-Erasable Programmable ROM (EEPROM)), and a data storage device 516, which communicate with each other via a bus 508.

In some embodiments, processing device 502 is provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

In some embodiments, computer system 500 further includes a network interface device 522 (e.g., coupled to network 574). In some embodiments, computer system 500 also includes a video display unit 510 (e.g., an LCD), an alphanumeric input device 512 (e.g., a keyboard), a cursor control device 514 (e.g., a mouse), and a signal generation device 520.

In some implementations, data storage device 516 includes a non-transitory computer-readable storage medium 524 on which store instructions 526 encoding any one or more of the methods or functions described herein, including instructions encoding components of FIG. 1 and for implementing methods described herein.

In some embodiments, instructions 526 also reside, completely or partially, within volatile memory 504 and/or within processing device 502 during execution thereof by computer system 500, hence, in some embodiments, volatile memory 504 and processing device 502 also constitute machine-readable storage media.

While computer-readable storage medium 524 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

In some embodiments, the methods, components, and features described herein are implemented by discrete hardware components or are integrated in the functionality of other hardware components such as application-specific integrated circuits (ASICs), field programmable gate arrays (FPGAs), digital signal processors (DSPs), or similar devices. In some embodiments, the methods, components, and features are implemented by firmware modules or functional circuitry within hardware devices. In some embodiments, the methods, components, and features are implemented in any combination of hardware devices and computer program components, or in computer programs.

Unless specifically stated otherwise, terms such as “performing,” “causing,” “determining,” “running,” “continuing,” “interrupting,” “initiating,” “identifying,” “training,” “providing,” “obtaining,” “outputting,” “predicting,” “receiving,” “updating,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. In some embodiments, the terms “first,” “second,” “third,” “fourth,” etc. as used herein are meant as labels to distinguish among different elements and do not have an ordinal meaning according to their numerical designation.

Examples described herein also relate to an apparatus for performing the methods described herein. In some embodiments, this apparatus is specially constructed for performing the methods described herein, or includes a general-purpose computer system selectively programmed by a computer program stored in the computer system. Such a computer program is stored in a computer-readable tangible storage medium.

The methods and illustrative examples described herein are not inherently related to any particular computer or other apparatus. In some embodiments, various general-purpose systems are used in accordance with the teachings described herein. In some embodiments, a more specialized apparatus is constructed to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and implementations, it will be recognized that the present disclosure is not limited to the examples and implementations described. The scope of the disclosure should be determined with reference to the following claims, along with the full scope of equivalents to which the claims are entitled.

In the claims:

1. A method comprising:
performing auto-classification of fluids to be used in a substrate processing system;
identifying portions of the substrate processing system;
performing positional awareness of the fluids associated with one or more of the portions of the substrate processing system; and
causing substrate processing via the substrate processing system based on the auto-classification, the portions of the substrate processing system, and the positional awareness.

2. The method of claim 1, wherein the auto-classification of the fluids is associated with classification of one or more of an inert fluid, a reactive oxidizing fluid, a non-reactive oxidizing fluid, or a corrosive fluid.

3. The method of claim 1, wherein the portions of the substrate processing system comprise piping, wherein at least one of the fluids is to pass through at least one of the one or more of the portions of the substrate processing system.

4. The method of claim 1, wherein the causing of the substrate processing comprises:
causing a flushing of a first portion of the portions of the substrate processing system; and
responsive to the flushing, causing a first fluid of the fluids to pass through the first portion of the substrate processing system.

5. The method of claim 1 further comprising receiving sensor data associated with the one or more of the portions of the substrate processing system.

6. The method of claim 1 further comprising:
identifying historical sensor data and historical performance data; and
training a machine learning model using data input comprising the historical sensor data and target output comprising the historical performance data to generate a trained machine learning model configured to provide output associated with predictive data, wherein the causing of the substrate processing is based on the predictive data.

7. The method of claim 1, wherein the causing of the substrate processing comprises:
identifying current sensor data;
providing input comprising the current sensor data to a trained machine learning model; and
receiving, from the trained machine learning model, output associated with predictive data, wherein the causing of the substrate processing is based on the predictive data.

8. A non-transitory machine-readable storage medium storing instructions which, when executed cause a processing device to perform operations comprising:
performing auto-classification of fluids to be used in a substrate processing system;
identifying portions of the substrate processing system;
performing positional awareness of the fluids associated with one or more of the portions of the substrate processing system; and
causing substrate processing via the substrate processing system based on the auto-classification, the portions of the substrate processing system, and the positional awareness.

9. The non-transitory machine-readable storage medium of claim 8, wherein the auto-classification of the fluids is associated with classification of one or more of an inert fluid, a reactive oxidizing fluid, a non-reactive oxidizing fluid, or a corrosive fluid.

10. The non-transitory machine-readable storage medium of claim 8, wherein the portions of the substrate processing system comprise piping, wherein at least one of the fluids is to pass through at least one of the one or more of the portions of the substrate processing system.

11. The non-transitory machine-readable storage medium of claim 8, wherein the causing of the substrate processing comprises:
causing a flushing of a first portion of the portions of the substrate processing system; and
responsive to the flushing, causing a first fluid of the fluids to pass through the first portion of the substrate processing system.

12. The non-transitory machine-readable storage medium of claim 8, wherein the operations further comprise receiving sensor data associated with the one or more of the portions of the substrate processing system.

13. The non-transitory machine-readable storage medium of claim 8, wherein the operations further comprise:
identifying historical sensor data and historical performance data; and
training a machine learning model using data input comprising the historical sensor data and target output comprising the historical performance data to generate a trained machine learning model configured to provide output associated with predictive data, wherein the causing of the substrate processing is based on the predictive data.

14. The non-transitory machine-readable storage medium of claim 8, wherein the causing of the substrate processing comprises:
identifying current sensor data;
providing input comprising the current sensor data to a trained machine learning model; and
receiving, from the trained machine learning model, output associated with predictive data, wherein the causing of the substrate processing is based on the predictive data.

15. A system comprising:
memory; and
a processing device coupled to the memory, the processing device to:
perform auto-classification of fluids to be used in a substrate processing system;
identify portions of the substrate processing system;
perform positional awareness of the fluids associated with one or more of the portions of the substrate processing system; and
cause substrate processing via the substrate processing system based on the auto-classification, the portions of the substrate processing system, and the positional awareness.

16. The system of claim 15, wherein the auto-classification of the fluids is associated with classification of one or more of an inert fluid, a reactive oxidizing fluid, a non-reactive oxidizing fluid, or a corrosive fluid.

17. The system of claim 15, wherein the portions of the substrate processing system comprise piping, wherein at least one of the fluids is to pass through at least one of the one or more of the portions of the substrate processing system.

18. The system of claim 15, wherein to cause the substrate processing, the processing device is to:
cause a flushing of a first portion of the portions of the substrate processing system; and
responsive to the flushing, cause a first fluid of the fluids to pass through the first portion of the substrate processing system.

19. The system of claim 15, wherein the processing device is further to receive sensor data associated with the one or more of the portions of the substrate processing system.

20. The system of claim 15, wherein to cause the substrate processing, the processing device is to:
identify current sensor data;
provide input comprising the current sensor data to a trained machine learning model; and
receive, from the trained machine learning model, output associated with predictive data, wherein the processing device is to cause the substrate processing based on the predictive data.
